(19) United States
(12) Patent Application Publication
(10) Pub. No.: US 2010/0216294 A1
(43) Pub. Date: Aug. 26, 2010

(54) METHOD OF FABRICATING A MICROELECTRONIC STRUCTURE INVOLVING MOLECULAR BONDING

(76) Inventors: Marc Rabarot, Saint-Egreve (FR); Christophe Dubarry, Claix (FR); Jean-Sébastien Moulet, Grenoble (FR); Aurélie Tauzin, Saint Egreve (FR)

Correspondence Address: BRINKS HOFER GILSON & LIONE, P.O. BOX 10395, CHICAGO, IL, 60610, US

(21) Appl. No.: 12/682,522

(22) PCT Filed: Oct. 10, 2008
(86) PCT No.: PCT/FR0208/001427

§ 371 Date: Apr. 9, 2010

(30) Foreign Application Priority Data
Oct. 12, 2007 (FR) 0758282

(51) Int. Cl. H01L 21/762; H01L 21/20

(52) U.S. Cl. 438/458; 438/478; 438/482; 257/E21.568; 257/E21.09

(57) ABSTRACT

Method of fabricating a microelectronic structure includes preparing a first structure having a first material different from silicon on a surface thereof and forming at least one covering layer of a second material by IBS (ion beam sputtering) and having a thickness of less than one micron, where the at least one cover layer has a free surface and molecular bonding the free surface to one face of a second structure where the at least one covering layer constitutes a bonding layer for the first and second structures.

### PRIORITY CLAIM

This application is a nationalization under 35 U.S.C. 371 of PCT Application No. PCT/FR2008/001427, filed Oct. 10, 2008, which claims priority to French Patent Application No. 0758282, filed Oct. 12, 2007, and incorporated by reference herein.

### TECHNICAL FIELD

The invention concerns a method of fabricating a microelectronic structure involving molecular bonding. It is aimed in particular, although not exclusively, at a fabrication method involving the formation of a thin layer along the bonding interface.

### BACKGROUND

As is known, a “microelectronic structure” is an element or an assembly produced using microelectronic means or techniques and usable in particular in methods of fabricating microelectronic and/or optical and/or micromechanical components; such a structure can include a substrate, for example in a semiconductor material, possibly combined with one or more other layers or substrates, so as to enable the formation of these components. These methods often involve substrates themselves formed of a number of layers, which explains this name for the structure, even in the case of a single substrate.

In this field of microelectronics, it is common to form thin layers, the thickness of which is typically of the order from a few tenths of a micron to a few microns.

Thus the method known as the “Smart Cut”® method enables a thin film to be detached from a donor substrate (or starting substrate or structure) and its transfer to another substrate (or layer) called the receiver substrate (or layer) (this can involve an intermediate receiver substrate between the starting substrate and the final receiver substrate). This method is covered in particular by the U.S. Pat. No. 5,374,564 (Bruel) and/or improvements thereon (see in particular the document U.S. Pat. No. 6,020,252 (Aspar et al.)).

To this end, the following steps are executed, for example:

1. bombardment of a face of the donor substrate with ions or atoms of one or more gaseous species (typically hydrogen and/or a rare gas, for example helium), in order to implant those ions in a concentration sufficient to create a dense layer of microcavities forming a weakened layer,

2. bringing this face of the donor substrate into intimate contact with an intermediate or final receiver substrate,

3. separation at the level of the weakened layer of microcavities, by application of a heat treatment and/or a separation stress between the two substrates (for example by inserting a blade between the two substrates at the level of the layer of microcavities and/or by the application of a tension and/or shear and/or bending stress and/or the application of waves such as ultrasound or microwaves of judiciously chosen power and frequency),

4. recycling of the donor substrate for further cycles comprising steps 1 to 3.

If the thin layer separated in this way from the donor substrate has been transferred onto an intermediate receiver substrate, there can be subsequent steps including bringing the face of the thin layer released by separation from the donor substrate into intimate contact with a final receiver substrate.

The substrate (or structure) can be of very varied kinds (both on the surface and in its bulk); it is often silicon, but can also be other semiconductor materials, for example those from group IV of the Periodic Table of the Elements, such as germanium, silicon carbide or silicon-germanium alloys, or materials from group III-V or group II-VI (GaN, GaAs, InP, etc.).

There exist a number of methods for producing an effective connection between the donor substrate and the receiver substrate, but molecular bonding (also known as direct bonding because there is no addition of material and thus no interposition of any adhesive) is a connecting method of particular interest in that it is capable in principle of ensuring very high mechanical strength, good thermal conductivity, a uniform thickness of the bonding interface, and the like.

It is fairly standard practice for the donor substrate to be a base substrate on top of which is a layer or a stack of layers. Thus a silicon donor substrate is typically covered with a layer of thermal silica obtained by simple heat treatment of the donor substrate.

One benefit of such a thermal oxide layer, which is easily formed on silicon, is that it enables molecular bonding of very high quality to be obtained. It is therefore natural that attempts have been made to form such oxide layers conducive to effective molecular bonding for other materials.

Now some materials, such as Ge, GaN, LiTaO₃, LiNbO₃, and the like, which can also be used in the target applications, produce thermal oxides that are not stable, notably from the thermal point of view, so that it is generally considered that it is preferable to avoid their formation. However, the material of the donor substrate concerned, at least in the portion thereof that is to donate the thin layer, may itself not be compatible with good molecular bonding with the receiver substrate with which it is to be brought into intimate contact. It can then be necessary to provide for the interposition of at least one so-called bonding layer (referring to the particular type of connection envisaged). Because such bonding layers cannot in this case be obtained by simple heat treatment of the surface of the donor substrate, a specific deposition treatment is therefore required.

Thus for materials having no stable oxide, recourse is generally had to the deposition onto at least one of the substrates to be connected of one or more thin layers (typically with thicknesses between a few tenths of a micron and a few hundred microns); these thin layers are chosen not only to enable good molecular bonding with a substrate but also to have good adhesion to the substrate onto which they are deposited.

Now some materials (or stacks of materials), whether treated or not (in particular whether or not having undergone component fabrication, for example microelectronic component fabrication, steps), are not able to withstand a temperature above a critical threshold, typically between 200° C. and 700° C. inclusive, depending on the materials. For example, germanium must not be heated to a temperature greater than 600° C. because there is then formed an oxide GeOₓ that is unstable with temperature; clearly the formation of any such oxide must be avoided. It follows from this that, during deposition, if any, of a bonding layer, it is necessary to take care not to reach or to exceed the critical threshold of any of the materials constituting the donor substrate.

Furthermore, some materials cannot be heated above a limit temperature between the implantation step and the bonding step, because this could cause a phenomenon of blistering or exfoliation resulting from untimely localized separation at the level of the implanted layer. Such a risk would occur, for example, from 350° C. with a GaN donor substrate and from 150° C. with an LiTaO₃ donor substrate.

It should be noted here that, to obtain at the scale of the substrates good transfer of films (possibly bearing circuits) by the aforementioned layer transfer technique, it is necessary for the molecular bonding to occur over the whole of the facing surfaces of the donor and receiver substrates; this is commonly referred to as “wafer bonding”. It is known how to obtain high bonding energies, typically of the order of 1 J/m², especially with silicon substrates.

In practice our extensive knowledge of the phenomena of molecular bonding of a thermal silicon oxide layer to the surface of a silicon substrate, and the high level of its bonding qualities, mean that this type of layer often serves as a reference for evaluating the bonding performance of another layer serving as a bonding layer.

The criteria that guarantee a good overall capacity for molecular (generally hydrophilic) bonding of a bonding layer are, in addition to its adhesion to the underlying substrate:

a very low surface roughness, homogeneous over the whole of the wafer,

a high level of hydrogen bonds generated on the surface, which depend on the nature of the material of the bonding layer and the type of activation, if any, applied to that layer to reinforce the bonding performance thereof,

a low level of particles deposited on or adsorbed into the surface, which constitute sites limiting the intimate contact between the facing surfaces at the moment of bonding.

An attempt is therefore made to satisfy at least some of the above parameters when seeking to affect a good bond.

If the roughness of the bonding layer is too high after it is deposited, it is possible to reduce it to make it compatible with a high bonding energy, for example and conventionally by mechanical-chemical polishing; the required roughness is typically less than or equal to 0.6 nm RMS as measured by an atomic force microscope (AFM) over areas of 1×1 μm² on silicon. However, this operation presupposes increasing the deposited thickness by an amount equal to that subsequently removed by the polishing to achieve the required roughness. However, there are situations in which increasing the thickness of the deposit is not possible or is not desirable for economic reasons, for example. There is therefore a requirement to be able to deposit a bonding layer (notably an oxide layer) having as deposited a low roughness, even one directly compatible with a high bonding energy, comparable with that obtained with the above reference, namely thermal silicon oxide.

Solutions well known to a person skilled in the art at this time for forming an oxide bonding layer consist in depositing an oxide by chemical vapor phase deposition, for example plasma-enhanced chemical vapor deposition (PECVD), or by physical vapor deposition (PVD). To increase the density and the adhesion of these deposits, they are generally produced in a temperature range from 200° C. to 800° C.; as has been shown, some materials cannot withstand treatment at these temperatures.

Furthermore, the oxides deposited in this way with a view to application of molecular bonding often have a number of drawbacks.

The first drawback frequently encountered is linked to the high surface roughness after PECVD or PVD deposition. The value of this roughness generally increases with the thickness of the deposited layer, at least for very thin layers (that is to say, in the present context, layers with thicknesses of the order of a few tens of nanometers). To alleviate this problem it is therefore necessary to have recourse to so-called “smoothing” mechanical-chemical polishing or etching means; however, as indicated above, such polishing consumes part of the thickness of the deposited layer.

A second drawback frequently encountered is linked to the low relative density of CVD type oxide deposits, notably compared to silicon thermal oxide. Now the density of the deposit often guarantees a good aptitude for bonding thanks to a high level of connections that can be activated on the surface just before bonding, and most importantly good thermal stability during subsequent annealing, notably for applications at high temperatures (above 600° C., or even above 1000° C. for the epitaxial deposition of a layer of GaN, for example). The solution generally adopted is to anneal the bonding layers after deposition. This operation is not always possible, however, either because of the temperature compatibility of the process (as in the case of the “Smart Cut®i process referred to above, where untimely separation must be avoided), or when the coefficients of thermal expansion (CTE) of the different materials present are too different (for example with a difference of more than 20% in absolute value). In this case, annealing causes tension or compression in the bonding layer, for example, which can in the end increase the roughness and most importantly weaken the adhesion and thus minimize the aptitude for molecular bonding. Finally, oxide deposits of low density are generally unstable and can be transformed by changes of state (partial crystallization, creep, etc.) during subsequent heat treatment. In a film transfer process, this deterioration of the oxide leads to many defects in the transferred film and weakens the bonding interface for epitaxial applications, for example.

A third drawback frequently encountered is linked to the high level of hydrogen incorporated in the CVD oxide layers, which is inherent to this deposition method. The hydrogen level generally increases as the temperature at which the oxide is deposited decreases. During annealing subsequent to deposition, these types of layers are generally transformed (by densification), releasing some of the hydrogen which can then accumulate at the bonding interface with the underlying substrate and cause numerous defects. In some cases, increasing the pressure of the gases accumulating around the defects of the interface opposes the adhesion forces and can generate catastrophic separation forces that cause separation of the wafers previously bonded at room temperature.

As a result of the above, for some applications, it is not known how to deposit onto a substrate, at a temperature at most equal to 200° C., an oxide layer of good quality, guaranteeing at the same time good adhesion to the substrate, low roughness after deposition, good thermal stability during subsequent steps of annealing at high temperatures (typically at least equal to 1000° C.) and a satisfactory aptitude for direct bonding. It is therefore sometimes impossible to deposit oxides on some types of substrate formed of one or more layers, whether treated or not.

In fact, this requirement exists not only when it is required to produce oxide layers, but also more generally when it is required to deposit onto a substrate a layer, whether of oxide or not, having the aforementioned properties.

### SUMMARY

To this end the invention proposes to exploit a particular type of deposition, notably of oxide, namely ion beam sputtering (IBS), which can be generated at very low temperatures (typically below 100° C., or even below 50° C.). The inventors have noticed that such an oxide layer deposited by IBS has particularly beneficial properties for subsequent molecular bonding with a substrate; such a layer has a very low roughness after deposition, even when the deposited layer has a thickness equal to or even greater than 400 nm, and a good density that gives it good thermal stability (without it being necessary to apply a subsequent densification annealing treatment); furthermore, such layer deposition can be preceded, in the same vacuum cycle as the deposition itself, by a step of etching the receiving face, encouraging adhesion, or by the deposition of other layers, for example one or more metal layers (notably Cr, Pt, Al, Ru, Ir).

Ion beam sputtering (IBS) is a PVD technique in which the ions are produced by a source and accelerated toward the material to be sputtered.

This particular technique is distinguished from known PVD techniques for producing layers (see above) by the fact that it occurs at a low temperature (for example at room temperature) whilst ensuring good adhesion of the deposited layer. Evaporation techniques can also be carried out cold, but cannot produce such adhesion.

The oxides deposited by beams of ions in this way, without heating, have from the deposition step morphological and thermo-chemical characteristics closer to those of a silicon thermal oxide than those of a standard CVD deposit:

low roughness (less than or equal to that of a thermal oxide),

high density (greater than or equal to that of oxides obtained by CVD sputtering),

a low intrinsic level of silanol (Si—OH) bonds, between that of CVD oxides and that of thermal oxide,

increased adhesion, thanks to a possible in situ scouring sequence, carried out by means of an ionic assistance beam that impinges on the deposit interface beforehand.

These properties confer on IBS type deposits a high aptitude for molecular bonding of microelectronic structures or substrates.

Moreover, IBS type oxides (such as SiO₂, TiO₂, Ta₂O₅, and the like) are deposited very slowly (typically at a rate of the order of one angstrom per second), close to the rate of the thermal oxidation of silicon, which allows good control of the deposited thickness (to within less than one nanometer).

For example, the respective roughness values of a 400 nm deposit of silicon oxide produced on silicon by IBS and in the form of a thermal oxide are respectively:

0.22 nm and 0.25 nm RMS roughness, and

2.02 nm and 2.60 nm PV roughness.

These roughness values were measured on 400 nm thick layers using an atomic force microscope (AFM) field of 1×1 μm² (these types of roughness are well known to a person skilled in the art; RMS stands for root mean square and PV stands for peak to valley).

In fact, it has already been proposed to produce layers of SiO₂, TIO₂, Ta₂O₅, etc. by IBS in the field of optics or optronics because of their optical characteristics (thickness, refractive index in particular), linked to the fact that this technology simultaneously enables good control of the stoichiometry and the thickness of the deposited layers (thanks to the moderate rate of deposition). In the case of SiO₂, see in particular the paper “Effect of the working gas of the ion-assisted source on the optical and mechanical properties of SiO2 films deposited by dual ion beam sputtering with Si and SiO2 as the starting materials”, Jean-Yee Wu and Cheng-Chung Lee, Applied Optics, Vol 45n N^{o} 15, 20 May 2006, pp 3510-3515.

However, those skilled in the art had not yet recognized that such deposits had particular qualities making them of very special interest as bonding layers for molecular bonding, for example during a layer transfer process.

As indicated above, these layers have, at the same time, a low surface roughness even for great thicknesses (a few hundred nanometers, or even a few tens of microns), a high density (or compactness) and a high thermal stability (a low level of hydrogen bonds incorporated in the layers compared to standard bonding layers of CVD type, for example, which reduces outgassing of hydrogen during annealing, which leads to good stability).

Accordingly, for exactly the same deposition temperature, or even a lower temperature, IBS deposits have fewer silanol (Si—OH) type bonds than the CVD type oxides conventionally used as molecular bonding layers. Moreover, as IBS layers can be deposited at low temperature (close to room temperature), their use enables molecular bonding layers to be produced on structures that cannot be significantly heated (for example a structure having an interface previously implanted and that can induce separation (as in the case of the “Smart Cut®” process)).

The IBS technology enables deposition not only of oxides but also of nitrides, metal species, oxynitrides (notably SiOₓN_{y}), and the like.

The invention therefore proposes a method of fabrication of a microelectronic structure including:

the preparation of a first structure having on the surface a first material,

the formation on the surface of this first structure, by ion beam sputtering (IBS), of at least one covering layer of a second material, this layer having a free surface,

the molecular bonding of this free surface to one face of a second structure.

It must be pointed out that the above definition encompasses the situation where, as indicated hereinafter, at least one underlying layer is disposed between the first structure and the covering layer: the covering layer is then not formed directly on the surface of the first structure (formed of the first material); nevertheless, because it is formed in the immediate vicinity of the latter surface, it is indeed situated on the surface of that structure, albeit indirectly via one or more underlying layers.

As explained above, ion beam sputtering is carried out at low temperature and leads to the formation of a bonding layer the properties of which enable the subsequent production of molecular bonding of very good quality.

Thus using the method of the invention leads to the formation of a structure including, on a starting substrate, at least one thin IBS type layer enabling molecular bonding of the donor substrate (or structure) with a receiver substrate (or structure).

The covering layer is preferably formed after scouring the surface of the first structure inside the enclosure in which the deposition by sputtering is effected.

Another covering layer is advantageously also formed on the second structure before the molecular bonding. This other covering layer is preferably also produced by ion beam sputtering. This other covering layer can be produced in the same second material as the first covering layer, which guarantees good molecular bonding.

The use of the invention is advantageously combined with the formation of a thin layer, i.e. ions are implanted in one or both of the first and second structures in order to form therein a buried layer of microcavities and, after molecular bonding, fracture of this structure is caused at the level of this buried layer of microcavities.

It is noteworthy that the implantation step can be carried out either before or after the formation of the IBS layer with no risk of causing shrinkage and separation of the implanted film during the deposition step.

This second material is preferably an oxide, preferably a silicon oxide. More generally, the bonding layer advantageously consists of a layer of oxide chosen from SiO₂, TiO₂, Ta₂O₅, HfO₂, and the like.

Another interesting possibility is for this second material to be a nitride, chosen for example from the group consisting of Si₃N₄, TiN, WN, CrN.

Another interesting possibility is for the second material to be an oxynitride, for example of silicon. The relative proportions of oxygen and nitrogen in the oxynitride can be fixed or vary within the thickness of the layer (to achieve this it suffices to vary the ion beam sputtering parameters).

A further interesting possibility is for the second material to be a metal element or a metal alloy, for example chosen from the group consisting of Cr, Pr, Al, Ru, Ir.

In a particularly interesting variant, more than one layer is deposited on the donor substrate, in particular there is below the covering layer at least one underlying layer, advantageously deposited by ion beam sputtering. One case of interest is that in which this underlying layer is produced in a metal material or a metal alloy and the covering layer is of oxide, which amounts to forming a buried electrode.

The bonding layer is advantageously amorphous.

The material on which the IBS layer is formed is preferably a material from group IV of the Periodic Table of the Elements, for example a semiconductor material such as silicon. It can equally be one of the following materials: germanium, gallium nitride, gallium arsenide, lithium tantalate or lithium niobate.

The thickness of the IBS oxide bonding layer is preferably between a few nanometers and a few hundred nanometers; the thickness of the layer is advantageously less than 1 micron, preferably at most equal to 600 nanometers.

The structure obtained in this way in practice has a roughness less than around 0.25 nm RMS.

To encourage bonding with the substrate or the receiving structure, it is advantageous to activate the surface of the IBS layer, for example, in a manner known in itself, by means of mechanical-chemical polishing or a UV-ozone treatment or using a reactive plasma.

Clearly, expressed differently, the invention therefore proposes a method of fabricating a microelectronic structure (the expression “microtechnology” is sometimes also used) by molecular bonding of a first structure and a second structure, wherein there is formed by ion beam sputtering on the surface of at least one of the two structures a bonding layer less than one micron thick, preferably less than 600 nm thick.

This bonding layer is preferably an oxide, a nitride or an oxynitride of an element different from that of which the underlying structure consists; this underlying structure advantageously consists of a material other than silicon having no stable thermal oxide, such as in particular germanium, gallium nitride, gallium arsenide, lithium tantalate or lithium niobate, whereas the bonding layer preferably includes silicon oxide. This bonding layer can be separated from this underlying structure by a metal layer, also advantageously deposited by ion beam sputtering.

This bonding layer is advantageously an electrical insulator and the molecular bonding is advantageously followed by a fracture step at a temperature at most equal to 400° C., preferably at most equal to 200° C., at the level of a layer of microcavities resulting from a previous step of implanting ions in the other of the structures so as to form a semiconductor on insulator type structure.

It may be noted that the use of ion beam sputtering is mentioned, fortuitously, in the document U.S. Publication No. 2007/0017438 for the formation of a layer for tangentially stressing underlying islets, with reference to an Si—W alloy, but that, to achieve such stressing, this layer is very thick (between several microns and several millimeters), to prevent any phenomenon of undulation; this is decidedly different from the formation of a thin covering (less than one micron thick) intended to serve as a bonding or attachment layer to enable good molecular bonding between two structures which, otherwise, could not be molecular bonded effectively. Furthermore, since the teaching of the above document is to form a layer that is the seat of a tangential stress, the document is a priori incompatible with the technical problem that the invention addresses of obtaining very high quality molecular bonding over a large bonding area; clearly the existence of a tangential stress at an interface tends to weaken it.

Accordingly, whereas in the context of the invention the IBS layer is a bonding layer which therefore is normally a buried layer, the non-stressing layer proposed in the above document is intended only to be released as a surface layer and then etched and heated in order to modify the stress level of the underlying islets.

### BRIEF DESCRIPTION OF THE DRAWING

Objects, features and advantages of the invention emerge from the following description given by way of nonlimiting illustrative example with reference to the appended drawings, in which:

FIG. 1 is a view in section of a donor substrate during implantation to form a weakened layer,

FIG. 2 is a view in section of that substrate after depositing a layer by ion beam sputtering,

FIG. 3 is a view of it after molecular bonding,

FIG. 4 is a view of it after separation at the level of the weakened layer,

FIG. 5 is a view of the remainder of the donor substrate, ready for a new cycle, and

FIG. 6 is a theoretical diagram of an ion beam sputtering deposition installation.

### DETAILED DESCRIPTION

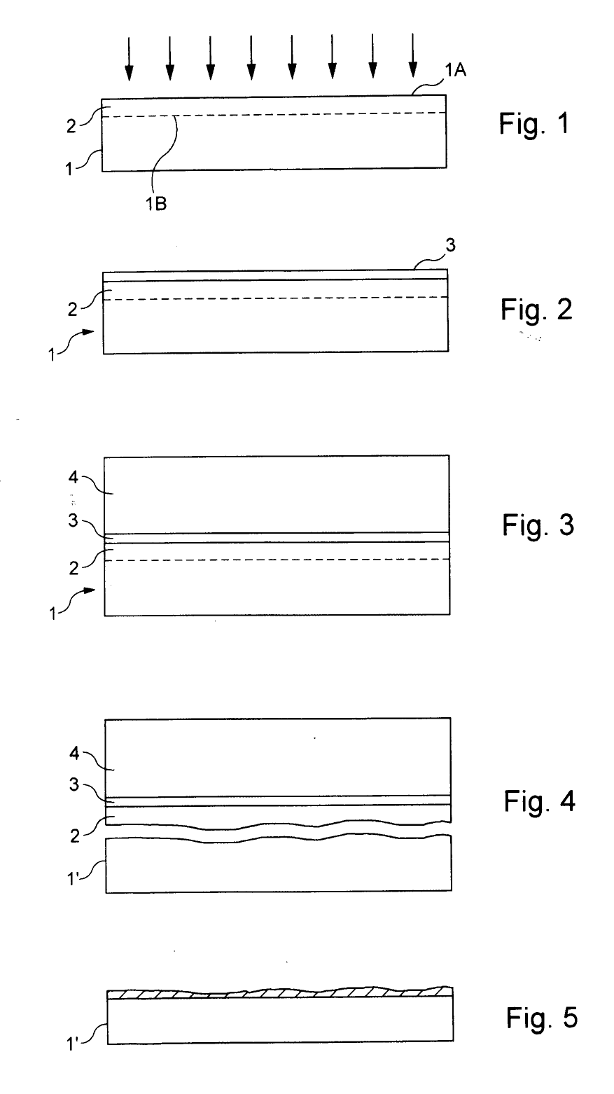

FIGS. 1 to 5 represent one example of a method employing the invention.

That method includes the following steps:

preparation of a substrate 1 constituting a first structure having a first material at least at the surface (or in the immediate vicinity thereof if a thin layer has been deposited thereon),

bombardment of a face 1A of that substrate with ions (or atoms) in order to implant those ions (or atoms) to create a buried layer 1B of microcavities defining with the surface 1A the future thin layer 2—see FIG. 1,

deposition on the surface of the first structure of an oxide layer 3 by ion beam sputtering at low temperature—see FIG. 2,

bonding of a receiver substrate 4 forming a second structure, by molecular bonding—see FIG. 3,

fracture at the level of the buried layer 1B of microcavities, so as to separate the layer 2 from the remainder 1′ of the donor substrate, by the application of a heat treatment and/or a detachment stress (for example the application of ultrasound or microwaves of appropriate power and frequency, or application of a tool, etc.)—see FIG. 4, and

recycling of the remainder 1′ of the donor substrate, possibly after polishing (cross-hatched area)—see FIG. 5.

It goes without saying that the undulations represented in FIGS. 4 and 5 are entirely exaggerated, aiming only to demonstrate the benefit of any polishing.

This method thus includes, in a situation of layer transfer (reference 2) from a donor substrate (or first structure) 1 to a receiver substrate (or second structure) 4, a step consisting in a deposition of oxide 3, of controlled thickness from a few nanometers to a few tenths of a micron, by IBS.

This deposition is carried out “cold”, i.e. at a temperature below 100° C., typically around 40° C. (this temperature corresponds to the surface temperature of the substrate because of the deposition), or even at room temperature. This deposit can therefore be produced on any substrate, treated or not, without risk of degrading the result of previous steps or the properties of the surface of the donor substrate.

In the example shown in FIGS. 1 to 5, this layer 3 deposited by IBS has the main function of serving as a bonding layer. Nevertheless, it can have other, additional functions such as, in particular:

an electrically or thermally insulating layer,

a sacrificial layer (for example for the production of microsystems such as acceleration or pressure sensors,and the like),

a mirror or optical filter layer (possible introduction of an optical function by stacking layers of different natures and/or thicknesses),

a layer (or stack of layers) for compensating mechanical stresses of any origin,

a buried electrode (for example a metal layer between a substrate and an oxide layer),

a barrier layer (for example of nitride such as TiN, WN,and the like).

The material constituting the layer deposited by IBS is thus an oxide (when producing a bonding layer), but can therefore alternatively be a nitride, an oxynitride, a metal element or alloy, and the like.

It should be noted that it is not necessary to carry out any densification treatment of the IBS oxides because they are already very dense, as soon as deposited, with a density compatible with bonding of very good quality.

Alternatively, the deposition of the IBS layer takes place before implantation.

Cleaning is advantageously carried out in the IBS deposition chamber, before deposition, so as to prepare the surface of the donor substrate, and thus to improve the adhesion of the layer deposited on the surface of that substrate. Such cleaning can consist in bombardment of the surface with neutral ions, such as argon or xenon ions (this preparation can be referred to as scouring).

This ion beam sputtering can be carried out in a number of specific ways, according to any specific features operative during its execution: thus there is the known RIBS (Reactive IBS) technology, but other alternatives can be used.

The DIBS (Dual IBS) technology in particular can be used, which also uses an assistance beam, which makes it possible to increase the compactness of the layers but also to control the stoichiometry of the layer during deposition, where appropriate by means of an additional gaseous top-up (for example of oxygen, in the case of oxide deposition).

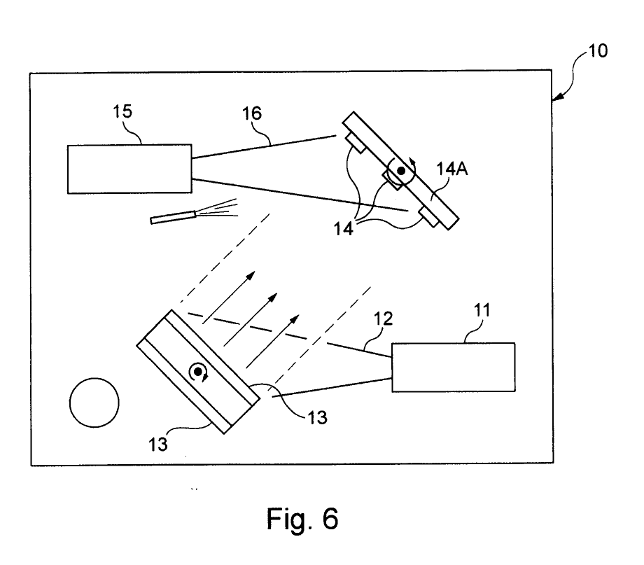

FIG. 6 is a theoretical diagram of an installation adapted to implement this DIBS technology in the case, for example, of forming a silicon oxide covering on a set of substrates.

There are disposed in a vacuum enclosure 10 (the numerical values below correspond, for example, to an OXFORD 500 type installation):

a source of ions (sputtering source) 11 that generates a beam 12 of mono-energetic positive ions (typically with an energy between 500 and 1500 eV) defined spatially. The beam, formed here of argon ions, bombards a target 13 consisting of the material to be deposited (SiO₂ here). The species sputtered are emitted into the half-space facing the target and condense on the substrates 14 (here carried by a planetary support 14A) to form the FIG. 2 covering layer 3 (not shown in FIG. 6),

an assistance source 15 emitting ions of lower energy (typically from 50 to 100 eV) in a beam 16 the purpose of which is to increase the compactness of the layers deposited on the substrates and also to control the stoichiometry of these thin layers during deposition (in this case it is possible to substitute for some or all of the flow of ionized neutral gas from the source 15 oxygen or another gas that reacts with the layer being formed); this assistance source can also be used as a source of flux for scouring the substrates before beginning the deposition as such.

The deposition chamber is advantageously “dry” pumped to prevent any particulate and organic contamination: the limit vacuum is typically 2.10⁸ Torr.

Layers with a typical thickness from 0.1 to 1 micron can be produced with or without an assistance source. In fact, this assistance source is advantageously used only for scouring the surface of the substrates, for example for five minutes. As indicated above, the neutral gas can be argon or xenon.

One example of the operating conditions of the OXFORD 500 apparatus referred to above is defined as follows:

deposition gun (xenon): voltage 1000 V, current 100 mA and flow rate 2.1 sccm (standard cubic centimeters per minute),

assistance gun (xenon): voltage 200 V, current 20 mA, flow rate 6 sccm,

4 sccm flow rate of oxygen added directly into the enclosure.

It should be remembered here that the IBS technology corresponds to very low deposition rates (typically of the order of one angstrom per second, to be compared to deposition rates of the order of 100 to 1000 angstroms per second in the case of the PECVD or LPCVD technologies), which contributes to their high density.

One way to evaluate the density of a thin covering is to measure the rate at which it is chemically etched (the density of a covering is inversely proportional to this rate).

The etching rates of the various types of SiO₂ oxides are indicated hereinafter for various conditions:

thermal (deposited at 1100° C.): 850 angstroms/min,

IBS (deposited at below 100° C.): 1050 angstroms/min,

LF PECVD (deposited at around 300° C.): 1600 angstroms/min,

LPCVD (HTO DCS) (deposited at around 900° C.): 1550 angstroms/min.

In the preceding paragraph, LF stands for “Low Frequency” and HTO DCS stands for “High Temperature Oxide DiChloroSiloxane”.

It should be noted that the rate of etching of the covering obtained by IBS is hardly higher than that of the thermal oxide, with the result that its density is hardly lower than that of that thermal oxide. On the other hand, it is seen that the rate of etching of this IBS covering is substantially lower than that of coverings obtained by CVD type techniques, and therefore that its density is significantly higher.

Oxides deposited by IBS therefore enable a bonding quality to be obtained that is comparable to that of a thermal oxide, even if it is not the oxide of the material constituting the bearer substrate, with the advantage of being carried out at very low temperature, and thus of being compatible with any type of substrate, in particular treated substrates.

If a high-temperature heat treatment is applied to the bonded structure obtained after separation (formed of the receiver substrate, the oxide layer and the thin layer separated from the remainder of the donor substrate), there are often encountered localized detachment, lifting or even separation of the transferred thin layer, by outgassing or transformation of the oxide layer if it is not sufficiently dense (PECVD or LPCVD). However this drawback has not occurred for IBS deposits, the high density of which confers on them excellent behavior at high temperatures and therefore enables the number of final defects in the structures to be reduced.

In the example of FIGS. 1 to 5, implantation takes place in the first structure; alternatively, this implantation takes place in the second structure (there can even be implantation in both structures).

Moreover, in this example, the covering layer is formed on the surface of this first structure, and directly (thus directly on the part of the substrate having the first material on its surface); alternatively, this covering layer is produced on the second structure; this covering layer can also be deposited indirectly on the surface of this first or second structure, on an under-layer (or underlying layer), formed on the surface of that structure (possibly also by ion beam sputtering). There can also be a covering layer on each of the two structures.

Examples of application of the invention are given hereinafter.

### Example 1

A substrate of crystalline GaN (⁷⁰Ga¹⁴N) is implanted with H ions under the following conditions:

energy: 60 keV,

dose: 3.5 10¹⁷ cm⁻².

A layer of SiO₂ between 500 nm and 1 micron thick is then deposited by IBS on the implanted substrate. Prior to the deposition step as such, the GaN substrate is cleaned in situ (in the IBS deposition enclosure) for five minutes by a scouring step.

The GaN substrate carrying the oxide layer is then bonded by molecular bonding to a sapphire substrate. To this end, mechanical-chemical polishing of the oxide layer is followed by brushing and rinsing of the wafers to be bonded, for example.

Alternatively, a plasma treatment is applied to the surface of the oxide layer, for example using an O₂ plasma.

Fracture is then caused at the level of the implanted layer, by a heat treatment in the range 200° C. to 400° C. A stable GaN/SiO₂/sapphire structure is obtained in this way, which can be used to produce light-emitting diodes (LEDs), for example. Because of its density, the oxide layer obtained by IBS is entirely suitable for a subsequent high-temperature epitaxy step (typically at a temperature between 1000° C. and 1100° C.) to form the active layers of the LEDs.

### Example 2

The starting point is a crystalline LiTaO₃ donor substrate.

A layer of SiO₂ 100 nm thick is then deposited by IBS on this donor substrate (after cleaning in situ for five minutes by a scouring step).

The LiTaO₃ substrate is then implanted through the oxide layer with H ions under the following conditions:

energy: 60 keV,

dose: 8 10¹⁶ cm⁻².

The LiTaO₃ substrate, with the oxide layer, is then bonded by molecular bonding to an LiTaO₃ substrate covered with a chromium bonding layer. The bonding is effected by chemical cleaning, for example, using a so-called “Caro” (H₂SO₄/H₂O₂) bath.

Fracture is then caused at the level of the implanted layer, by a heat treatment of one hour at 150° C. There is obtained in this way an LiTaO₃/SiO₂/Cr/LiTaO₃ structure that can be used to produce ferro-electric memories, for example.

### Example 3

The starting point is a germanium substrate.

A layer of SiO₂ 300 nm thick is then deposited by IBS on the donor substrate. Before deposition, the substrate is cleaned in situ for 56 minutes by a scouring step.

The substrate is then implanted through the oxide layer with H ions under the following conditions:

energy: 80 keV,

dose: 6 10¹⁶ cm⁻².

The substrate, with the oxide layer, is then bonded by molecular bonding to a silicon substrate covered with a layer of thermal oxide. To this end, mechanical-chemical polishing of the oxide layer can be followed by brushing and rinsing of the wafers, for example.

Fracture is then caused at the level of the implanted layer, by a heat treatment of one hour at 330° C. There is obtained in this way a Ge/SiO₂/SiO₂/Si structure, also known as GeOI (Germanium On Insulator) that can be used to produce microelectronic components, for example.

### Example 4

The starting point is an LiTaO₃ substrate in which:
H ions are implanted under the following conditions:

energy: 60 keV,

dose: 8 10¹⁶ cm⁻², and
He ions are implanted under the following conditions:

energy: 100 keV,

dose: 5 10¹⁶ cm⁻².

There is then deposited by IBS a layer of chromium (or alternatively of platinum) 100 nm thick and possibly a layer of SiO₂ 200 nm thick.

This substrate is bonded by molecular bonding to another LiTaO₃ substrate on which has previously been deposited by IBS a 400 nm layer of SiO₂, followed by mechanical-chemical polishing and brushing.

Fracture is caused at a temperature below 200° C., for example by application of mechanical stresses. An LiTaO₃/electrode/insulator/LiTaO₃ structure is obtained in this way.

A coating can optionally be deposited on the free surface followed by polishing.

### Example 5

The starting point is an LiNbO₃ donor substrate.

He ions are implanted in this substrate under the following conditions:

energy: 250 keV,

dose: 3 10¹⁶ cm⁻².

A 600 nm thick layer of SiO₂ is then deposited by IBS.

This substrate covered with SiO₂ is bonded by molecular bonding to a second silicon substrate covered with a 600 nm layer of SiO₂, also by IBS.

Fracture is caused at the level of the implanted layer and produces an Si/SiO₂/LiNbO₃ structure which therefore includes a buried insulator layer.

1. A method for fabricating a microelectronic structure, the method comprising:
preparing first structure having a first material on a surface thereof, the first material comprising a non-silicon material,
forming at least one covering layer of a second material comprising an oxide, a nitride or an oxynitride on the surface of the first structure by ion beam sputtering (IBS), the at least one covering layer having a thickness of less than one micron and having a free surface, and
molecular bonding the free surface to one face of a second structure, wherein the at least one covering layer comprises a bonding layer for the first and second structures.

2. The method according to claim 1 further comprising scouring the surface of the first structure inside an enclosure for the ion beam sputtering before forming the at least one covering layer.

3. The method according to claim 1, further comprising forming a further covering layer on the second structure before the molecular bonding.

4. The method according to claim 3, wherein forming the further covering layer comprises forming the covering layer by ion beam sputtering.

5. The method according to claim 3, wherein forming the further covering layer comprises forming the same second material as the first covering layer.

6. The method according to claim further comprising:
implanting ions in one or both of the first and second structures in order to form therein a buried layer of microcavities; and
after molecular bonding the free face, fracturing the first or second structures, or both, the buried layer of microcavities at a temperature less than 400° C.

7. The method according to claim 1, wherein forming at least one covering layer of a second material comprises forming an oxide of silicon.

8. The method according to any of claim 1, wherein forming at least one covering layer of a second material comprise forming SiO₂, TiO₂, Ta₂O₅, or HfO₂.

9. The method of claim 1, wherein forming at least one covering layer of a second material comprises forming Si₃N₄, TiN, WN, or CrN.

10. The method according to claim 1, wherein forming at least one covering layer of a second material comprises forming an oxynitride of silicon.

11. The method according to claim 10, wherein relative proportions of oxygen and nitrogen are varied within the thickness of the at least one covering layer.

12. The method according to claim 1 further comprising depositing at least one underlying layer by ion beam sputtering before depositing the at least one covering layer.

13. The method according to claim 12, wherein depositing the at least one underlying layer comprises depositing a metallic material or a metal alloy, and depositing the at least one covering layer comprises depositing an oxide.

14. The method according to claim 1, wherein depositing the at least one covering layer comprises depositing an amorphous material.

15. The method according to claim 1, wherein preparing a first structure having a first material comprises preparing a first structure having a semiconductor material.

16. The method according to claim 1, wherein preparing a first structure having a first material comprises preparing a first structure having a material comprising germanium, gallium nitride, gallium arsenide, lithium tantalate or lithium niobate.
